(19) United States
(12) Patent Application Publication
(10) Pub. No.: US 2006/0113667 A1
(43) Pub. Date: Jun. 1, 2006

(54) Bond pad structure for gold wire bonding to copper low K dielectric silicon devices

(76) Inventors: Chok Chia, Cupertino, CA (US); Qwai Low, Cupertino, CA (US); John McCormick, Palo Alto, CA (US)

Correspondence Address: LSI LOGIC CORPORATION, 1621 BARBER LANE, MS: D-106, MILPITAS, CA, 95035, US

(21) Appl. No.: 10/999,423

(22) Filed: Nov. 30, 2004

(51) Int. Cl. H01L 21/44; H01L 29/40

(52) U.S. Cl. 257/737; 438/613; 257/781; 438/614

(57) ABSTRACT

A bond pad structure which improves the reliability of the gold bonds, and thus, of the device. The bond pad structure allows for small gold bonds, which increases the density of the device. One design provides that the aluminum pad is connected to the copper IO strap at one end only. As such, expansion of the aluminum pad is not constrained. Another design provides that a segmented or un-segmented square copper ring is provided under the aluminum pad. There is effectively no copper provided under the aluminum pad in the area under the gold ball band. This reduces the restriction of the expansion of the aluminum pad. Yet another design provides for a reduced copper pad size under the aluminum pad, preferably just large enough for electrical connection.

### BACKGROUND

The present invention generally relates to bond pad structures, and more specifically relates to a bond pad structure for gold wire bonding to copper low K dielectric silicon devices.

A conventional bond pad stack design is illustrated (via an exploded view) in FIG. 1, wherein a gold ball bond 10 is bonded to an aluminum pad 12, which caps a copper pad 14. Typically, the copper pad 14 is either slotted as shown in FIG. 1, or is solid in design, and is disposed on a low K dielectric material 16. The design illustrated in FIG. 1 (i.e., wherein gold bonds to aluminum capped copper pads over low K dielectric material) causes intermetallic formations and subsequently kirkendall voiding in the bond when aged in temperature. This can cause the bond to fail, which is a reliability problem. The growth of the intermetallic is caused by stress in the aluminum and copper metal stack, which lies above a low K film.

Existing solutions to this problem include careful control of bonding parameters. However, bonding parameters are difficult to control in the manufacturing environment, and this does not completely resolve the problem. Additional existing solutions include etching and cleaning of the bond pads, and providing larger bonds. However, the additional processing steps required to etch and clean the bond pads increases cost and does not entirely solve the problem, and providing larger bonds increases the die size and adds cost.

### OBJECTS AND SUMMARY

An object of an embodiment of the present invention is to provide a bond pad structure which effectively eliminates the stress typically caused by the copper metal on the bond.

Another object of an embodiment of the present invention is to provide a bond pad structure which improves the reliability of the gold bonds, and thus, of the device.

Yet another object of an embodiment of the present invention is to provide a bond pad structure which allows for small gold bonds, which increases the density of the device.

Briefly, and in accordance with at least one of the foregoing objects, an embodiment of the present invention provides a modified bond pad structure wherein a portion of the copper metallization is etched away, leaving only aluminum metal cap in contact with the gold ball band. The copper metal under the bond area is removed. This removes the stress caused by the copper metal on the bond. The perimeter of the bond pads remain unchanged so as to not alter the design of the device.

Specifically, one embodiment of the present invention provides a bond pad structure wherein the aluminum pad is connected to the copper IO strap at one end only. As such, expansion of the aluminum pad is not constrained.

Another embodiment of the present invention provides a bond pad structure wherein a square copper ring is provided under the aluminum pad. The square copper ring can be provided as being segmented, such as provided only at the corners of the square, or un-segmented. Either way, there is effectively no copper provided under the aluminum pad in the area under the gold ball band, and this reduces the restriction of the expansion of the aluminum pad.

Yet another embodiment of the present invention provides a bond pad structure wherein a reduced copper pad size is provided under the aluminum pad, preferably just large enough for electrical connection.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein:

FIG. 1 is an enlarged, perspective view of a conventional bond pad stack design;

FIG. 2 is an enlarged, perspective view of a bond pad stack design which is in accordance with an embodiment of the present invention, wherein the aluminum pad is connected to the copper IO strap at one end only;

FIG. 3 is an enlarged, perspective view of a bond pad stack design which is in accordance with another embodiment of the present invention, wherein a segmented square copper ring is provided under the aluminum pad;

FIG. 4 is an enlarged, perspective view of a bond pad stack design which is in accordance with still yet another embodiment of the present invention, wherein a non-segmented square copper ring is provided under the aluminum pad;

FIG. 5 is an enlarged, perspective view of a bond pad stack design which is in accordance with yet another embodiment of the present invention, wherein a reduced copper pad size is provided under the aluminum pad, preferably just large enough for electrical connection;

FIG. 6 is a block diagram which illustrates a method which can be used to make any of the bond pad stack designs illustrated in FIGS. 2, 3 or 4, wherein the method is in accordance with an embodiment of the present invention;

FIG. 7 is a block diagram which illustrates a more specific method which can be used to make the bond pad stack design illustrated in FIG. 2, wherein the method is in accordance with an embodiment of the present invention;

FIG. 8 is a block diagram which illustrates a more specific method which can be used to make either one of the bond pad stack designs illustrated in FIGS. 3 and 4, wherein the method is in accordance with an embodiment of the present invention; and

FIG. 9 is a block diagram which illustrates a method which can be used to make the bond pad stack design illustrated in FIG. 5, wherein the method is in accordance with an embodiment of the present invention.

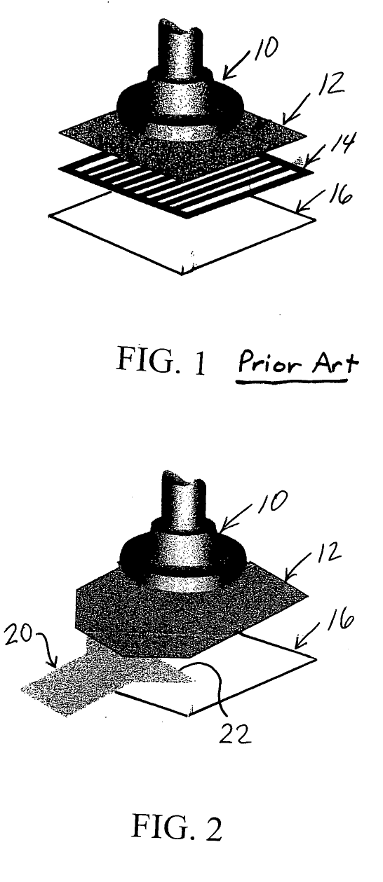

### DESCRIPTION

While the invention may be susceptible to embodiment in different forms, there are shown in the drawings, and herein will be described in detail, specific embodiments of the invention. The present disclosure is to be considered an example of the principles of the invention, and is not intended to limit the invention to that which is illustrated and described herein.

FIGS. 2-5 illustrate different bond pad structures, each of which is in accordance with a different embodiment of the present invention. Each effectively reduces or eliminates the stress typically caused by copper metal on a gold ball bond. Each design improves the reliability of the gold bonds, and thus, of the device. Additionally, each bond pad structure allows for small gold bonds, which increases the density of the device.

FIG. 2 illustrates an embodiment of the present invention (in exploded view) wherein a copper IO strap 20 is provided on a low K dielectric substrate 16. An aluminum pad 12 is connected to the copper IO strap 20 at one end 22 only. A gold ball bond 10 is bonded to the aluminum pad 12, such that the end 22 of the copper IO strap 20 is not disposed under the gold ball bond 10. As such, expansion of the aluminum pad 12 is not constrained.

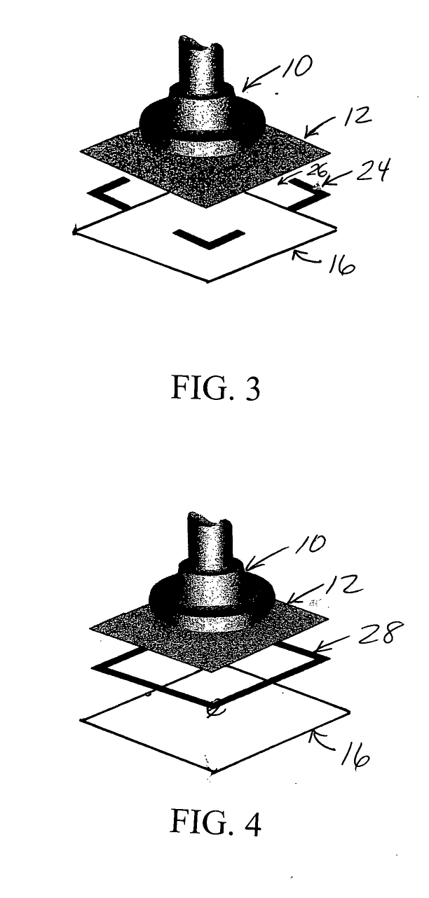

FIG. 3 illustrates an embodiment of the present invention (in exploded view) wherein a segmented square copper ring 24 is provided on the dielectric substrate 16 and under the aluminum pad 12. Specifically, the design provides for a modified bond pad structure wherein a portion of the copper metallization is etched away (i.e., the copper which used to be at section 26 in FIG. 3), leaving only aluminum metal cap 12 in contact with the gold ball band 10. The copper metal under the bond area is removed. This removes the stress caused by the copper metal on the bond. The design shown in FIG. 4 is very similar to that which is shown in FIG. 3, except the square copper ring 28 is not segmented.

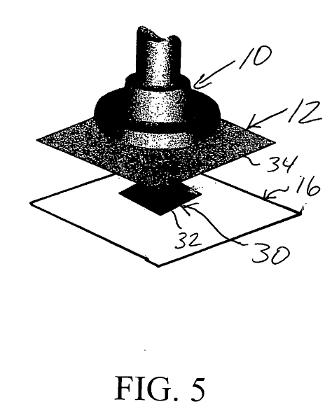

In the embodiment shown in FIG. 5, the copper pad 30 is provided as being reduced in size, preferably just large enough for electrical connection. As shown, a perimeter 32 of the copper pad 30 is smaller than a perimeter 34 of the aluminum pad 12. By providing less copper under the aluminum pad 12, the pad 12 is restricted less from expanding.

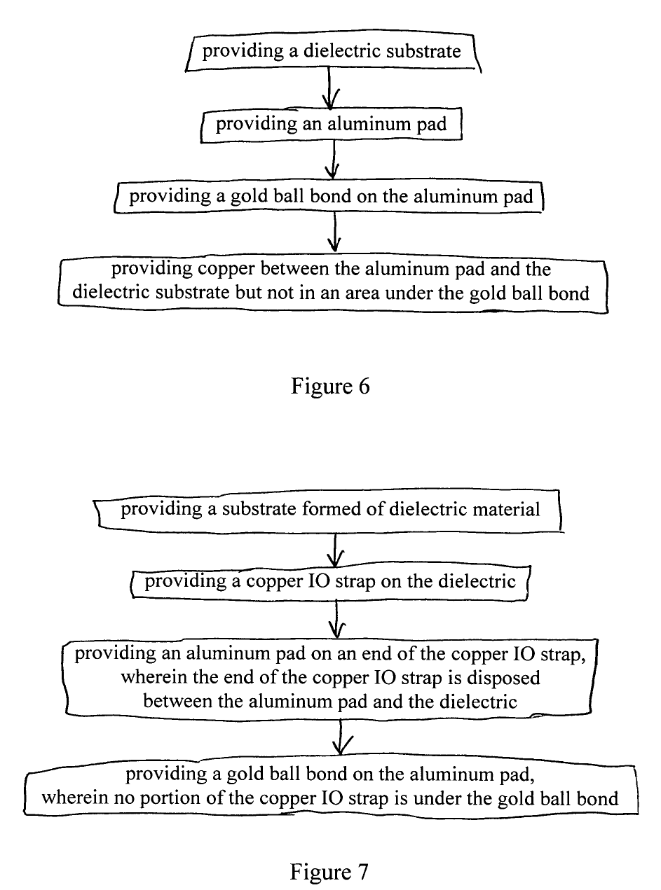

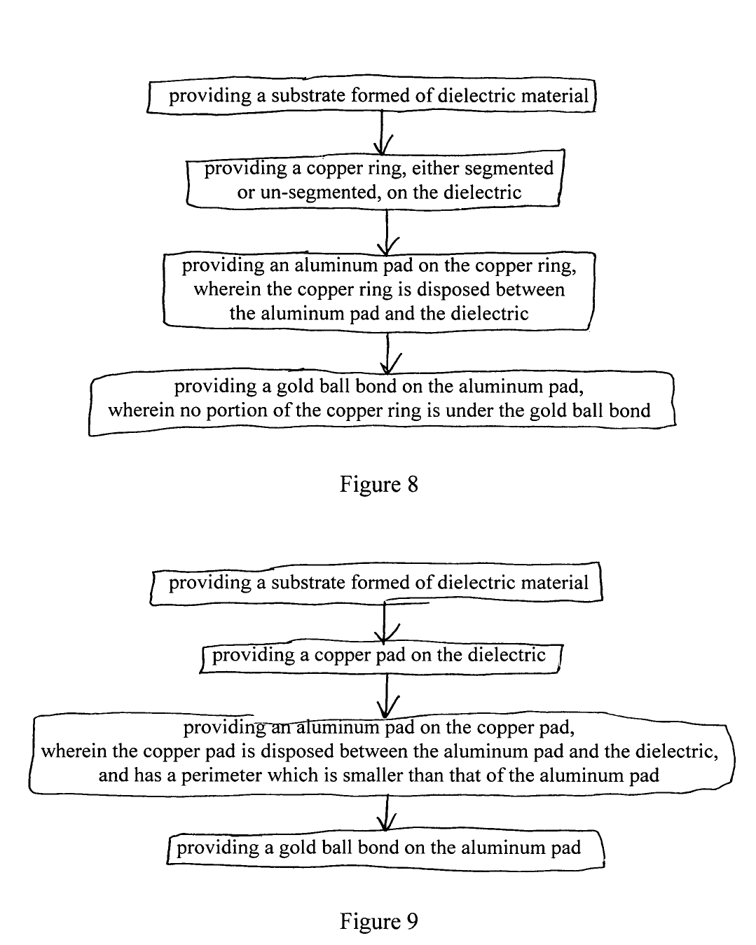

With regard to the block diagrams shown in FIGS. 6-8, FIG. 6 illustrates a method which can be used to make any of the bond pad stack designs illustrated in FIGS. 2-4, FIG. 7 illustrates a more specific method which can be used to make the bond pad stack design illustrated in FIG. 2, and FIG. 8 illustrates a more specific method which can be used to make either one of the bond pad stack designs illustrated in FIGS. 3 or 4. Finally, FIG. 9 illustrates a method which can be used to make the bond pad stack design illustrated in FIG. 5. Each of the block diagrams illustrated in FIGS. 6-9 is self-explanatory.

While embodiments of the present invention are shown and described, it is envisioned that those skilled in the art may devise various modifications of the present invention without departing from the spirit and scope of the appended claims.

1. A bond pad structure comprising: a dielectric substrate; an aluminum pad; a gold ball bond on the aluminum pad, copper in direct contact with the aluminum pad and on a sure of the dielectric substrate but not m an arena under the gold ball bond nor under any portion of the dielectric substrate.

2. A bond pad structure as recited in claim 1, wherein the copper between he aluminum pad and the dielectric substrate comprises an end of a copper IO strap.

3. A bond pad structure as recited in claim 1, wherein the copper between the aluminum pad and the dielectric substrate comprises a square copper ring.

4. A bond pad structure as recited in claim 3, wherein the ring is segmented.

5. A bond pad structure as recited in claim 3, wherein the ring is not segmented.

6. A bond pad structure comprising: a dielectric substrate; an aluminum pad having a perimeter; a gold ball bond on the aluminum pad; a copper pad in direct contact with the aluminum pad and on a surface of the dielectric substrate, said copper pad having a perimeter which is smaller than the perimeter of the aluminum pad, and having no portion which is under any portion of the dielectric substrate.

7. A method of forming a bond pad structure comprising providing a dielectric substrate; providing an aluminum pad; providing a gold ball bond on the aluminum pad; and providing copper in direct contact with the aluminum pad and on a surface of the dielectric substrate but not in an area under the gold ball bond nor under any portion of the dielectric substrate.

8. A method as recited in claim 7, wherein the step of providing copper between the aluminum pad and the dielectric substrate comprises providing an end of a copper IO strap between the aluminum pad and the dielectric substrate.

9. A method as recited in claim 7, wherein the step of providing copper between the aluminum pad and the dielectric substrate comprises providing a square copper ring between the aluminum pad and the dielectric substrate.

10. A method as recited in claim 7, wherein the step of providing copper between the aluminum pad and the dielectric substrate comprises providing a non-segmented square copper ring between the aluminum pad and the dielectric substrate.

11. A method as recited in claim 7, wherein the step of providing copper between the, aluminium pad and the dielectric substrate comprises providing a segmented square copper ring between the aluminum pad and the dielectric substrate.

12. A method of forming a bond pad structure comprising: providing a dielectric substrate; providing an aluminum pad having a perimeter, providing a gold ball bond on the aluminum pad; and providing a copper pad between in direct contact with the aluminum pad and on a surface of the dielectric substrate, wherein the copper pad has a perimeter which is smaller than the perimeter of the aluminium pad, and having no portion which is under any portion of the dielectric substrate.
